(19) United States
(12) Patent Application Publication
(10) Pub. No.: US 2010/0237920 A1
(43) Pub. Date: Sep. 23, 2010

(54) PEAK MAGNETIC FLUX REGULATION METHOD, APPARATUS, AND SYSTEM USING SAME

(76) Inventors: Yen-Hui Wang, Hsinchu City (TW); Chia-Chien Hung, Lujhu Township (TW)

Correspondence Address: SINORICA, LLC, 2275 Research Blvd., Suite 500, ROCKVILLE, MD, 20850, US

(21) Appl. No.: 12/406,156

(22) Filed: Mar. 18, 2009

(51) Int. Cl. H03K 7/08

(52) U.S. Cl. 327/176

(57) ABSTRACT

The present invention discloses a peak magnetic flux regulation method for a power conversion via magnetic flux transformation through an inductive component, comprising the steps of: generating an adaptive reference voltage according to voltage comparison of a current sensing voltage and an expected peak voltage; and generating a PWM signal according to voltage comparison of said current sensing voltage and said adaptive reference voltage. Furthermore, the present invention also provides a peak magnetic flux regulation apparatus for a power conversion, and a system using the peak magnetic flux regulation apparatus for a power conversion.

### BACKGROUND OF THE INVENTION

1. Field of the Invention

The present invention relates to switching power conversions, and more particularly to open loop switching power conversions via magnetic flux transformation through an inductive component.

2. Description of the Related Art

In supplying the power for a LED (Light Emitting Diode) module, an open loop switching power conversion architecture is widely adopted due to cost issue. The open loop switching power conversion features a concise circuit topology by eliminating the transformer and the voltage feedback network.

FIG. 1 shows the architecture of a typical open loop LED driving circuit comprising a PWM controller. As shown in FIG. 1, the architecture realizing an open loop current regulation application, at least includes: a PWM controller 100, a diode 101, a capacitor 102, an inductor 103, a LED module 104, an NMOS transistor 105, and a resistor 106.

In the architecture of the typical open loop LED driving circuit, the PWM controller 100 is used for generating a PWM signal Vₒᵤₜ with a duty cycle in response to a current sensing voltage V_{CS}.

The diode 101 is used for releasing the magnetic flux in the inductor 103 to drive the LED module 104.

The capacitor 102 is used for filtering the noise from a main power input voltage V_{IN}.

The inductor 103 is used for carrying the magnetic flux to provide a current to drive the LED module 104.

The LED module 104 is the load of the open loop LED driving circuit

The NMOS transistor 105 is used to control the magnetic flux transformation through the inductor 103 in response to the PWM signal Vₒᵤₜ. When the NMOS transistor 105 is on, the LED module 104, the inductor 103, the NMOS transistor 105, and the resistor 106 will constitute a conduction path to store the magnetic flux in the inductor 103; when the NMOS transistor 105 is off, the LED module 104, the inductor 103, and the diode 101 will constitute a conduction path to release the magnetic flux from the inductor 103.

Through a periodic on-and-off switching of the NMOS transistor 105, which is driven by the PWM signal Vₒᵤₜ generated from the PWM controller 100, the input power from the main power input voltage V_{IN} is transformed through the inductor 103 to the LED module 104 in the form of a regulated current.

The resistor 106 is used for converting the current, which corresponds to the magnetic flux being stored in the inductor 103, to the current sensing voltage V_{CS} when the NMOS transistor 105 is on.

Due to an off delay contributed by a propagation delay in the PWM controller 100 and a switching-off delay in the NMOS transistor 105, the peak value of the current sensing voltage V_{CS} will exceed an expected value with an exceeding amount during the off delay period. Please refer to FIG. 2, which shows the waveform diagram of the current sensing voltage V_{CS} corresponding to a value of the main power input voltage V_{IN}. As can be seen in FIG. 2, the exceeding amount of the current sensing voltage V_{CS} is proportional to the product of the main power input voltage V_{IN} and the off delay.

If the main power input voltage V_{IN} is changed with a different value, the exceeding amount will also be different. Please refer to FIG. 3, which shows the waveform diagram of the current sensing voltage V_{CS} corresponding to two different values of the main power input voltage V_{IN}. As can be seen in FIG. 3, the exceeding amount of the current sensing voltage V_{CSH}, which corresponds to a higher value of the main power input voltage V_{IN}, is larger than that of the current sensing voltage V_{CSL}, which corresponds to a lower value of the main power input voltage V_{IN}. As a result, the light intensity of the LED module 104 will be inconsistent if the value of the main power input voltage V_{IN} is changed.

One solution that a prior art utilizes to regulate the peak value of the current sensing voltage is adopting a modified reference voltage methodology. Please refer to FIG. 4, which shows the waveform diagram for the peak value regulation of the current sensing voltage V_{CS} of the prior art which adopts the modified reference voltage methodology. As shown in FIG. 4, the modified reference voltage V_{ref} is ramping up with a slope versus time t so that the V_{CSH} will reach the modified reference voltage V_{ref} before the V_{CSL} does. By adjusting the slope, the peak value of the V_{CSH} and that of the V_{CSL} may be at the same level. However, there are some drawbacks corresponding to this solution. First, the off delay is not known exactly and depends on the application so it will take much time in determining the proper value of the off delay. Second, the slope of the modified reference voltage V_{ref} is so critical that only one value of the slope can fulfill the peak value regulation request. Third, the analog ramping up waveform of the modified reference voltage V_{ref} is sensitive to variation of temperature, humidity, or noise, etc.

Therefore, there is a need to provide a solution that is robust in circuit topology, efficient, and cost effective for the peak value regulation of the current sensing voltage.

Seeing this bottleneck, the present invention proposes a solution of novel topology, needless of exploring the exact value of the off delay, for the peak value regulation of the current sensing voltage.

### SUMMARY OF THE INVENTION

The primary objective of the present invention is to provide a peak magnetic flux regulation method for a power conversion via magnetic flux transformation through an inductive component in that the peak magnetic flux regulation can be accomplished in a digital way, needless of exploring the exact value of the off delay.

Another objective of the present invention is to further provide a peak magnetic flux regulation apparatus for a power conversion via magnetic flux transformation through an inductive component in that the peak magnetic flux regulation can be accomplished in a digital way, needless of exploring the exact value of the off delay.

Still another objective of the present invention is to further provide a system using a peak magnetic flux regulation apparatus for a power conversion via magnetic flux transformation through an inductive component in that the peak magnetic flux regulation can be accomplished in a digital way, needless of exploring the exact value of the off delay.

To achieve the foregoing objectives of the present invention, a peak magnetic flux regulation method for a power conversion via magnetic flux transformation through an inductive component is proposed, the method comprising the steps of: generating an adaptive reference voltage according to voltage comparison of a current sensing voltage corresponding to the magnetic flux and an expected peak voltage, wherein the adaptive reference voltage is stepped down by a predetermined value each time the current sensing voltage exceeds the expected peak voltage; and generating a PWM signal according to voltage comparison of the current sensing voltage and the adaptive reference voltage.

To achieve the foregoing objectives, the present invention further provides a peak magnetic flux regulation apparatus for a power conversion via magnetic flux transformation through an inductive component, comprising: an adaptive reference voltage generator, used for generating an adaptive reference voltage according to voltage comparison of a current sensing voltage corresponding to the magnetic flux and an expected peak voltage, wherein the adaptive reference voltage is stepped down by a predetermined value each time the current sensing voltage exceeds the expected peak voltage; and a first comparator, used for generating a PWM signal according to voltage comparison of the current sensing voltage and the adaptive reference voltage.

To achieve the aforesaid objectives, the present invention further provides a system using a peak magnetic flux regulation apparatus for a power conversion via magnetic flux transformation through an inductive component, comprising: an adaptive reference voltage generator, used for generating an adaptive reference voltage according to voltage comparison of a current sensing voltage corresponding to the magnetic flux and an expected peak voltage, wherein the adaptive reference voltage is stepped down by a predetermined value each time the current sensing voltage exceeds the expected peak voltage; a first comparator, used for generating a PWM signal according to voltage comparison of the current sensing voltage and the adaptive reference voltage; and a power conversion unit, responsive to the PWM signal to provide the power conduction path.

To make it easier for our examiner to understand the objective of the invention, its structure, innovative features, and performance, we use a preferred embodiment together with the accompanying drawings for the detailed description of the invention.

### BRIEF DESCRIPTION OF THE DRAWINGS

FIG. 1 is the architecture of a typical open loop LED driving circuit comprising a PWM controller.

FIG. 2 is the waveform diagram of the current sensing voltage V_{CS} of the typical open loop LED driving circuit in FIG. 1, corresponding to a value of the main power input voltage V_{IN}.

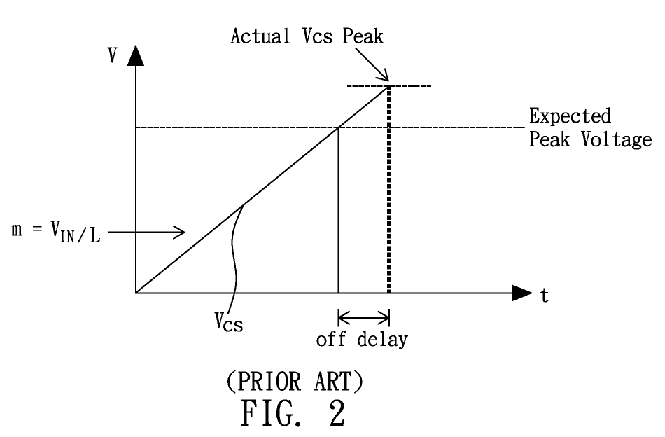

FIG. 3 is the waveform diagram of the current sensing voltage V_{CS} of the typical open loop LED driving circuit in FIG. 1, corresponding to two different values of the main power input voltage V_{IN}.

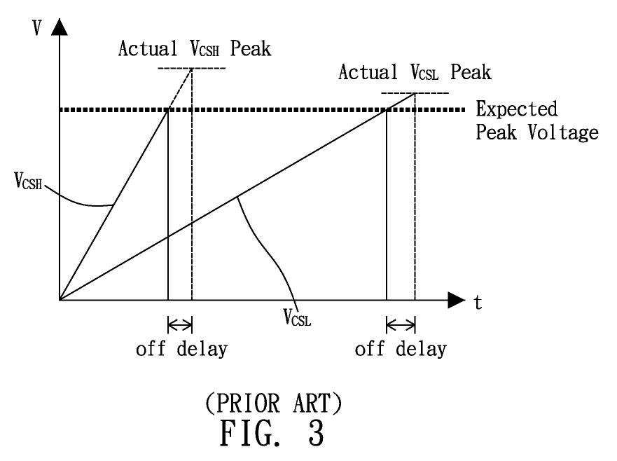

FIG. 4 is the waveform diagram for the peak value regulation of the current sensing voltage V_{CS} of a prior art adopting a modified reference voltage methodology.

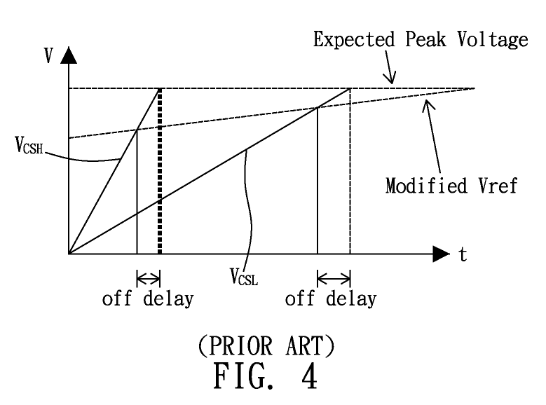

FIG. 5 is the block diagram of an apparatus according to a preferred embodiment of the present invention, for regulating the peak value of a current sensing voltage V_{CS}.

FIG. 6 is the flow chart for generating an adaptive V_{ref} according to a preferred embodiment of the present invention.

FIG. 7 is the detailed block diagram of an apparatus according to a preferred embodiment of the present invention, for regulating the peak value of the current sensing voltage V_{CS}.

### DETAILED DESCRIPTION OF THE PREFERRED EMBODIMENTS

The present invention will be described in more detail hereinafter with reference to the accompanying drawings that show the preferred embodiment of the invention.

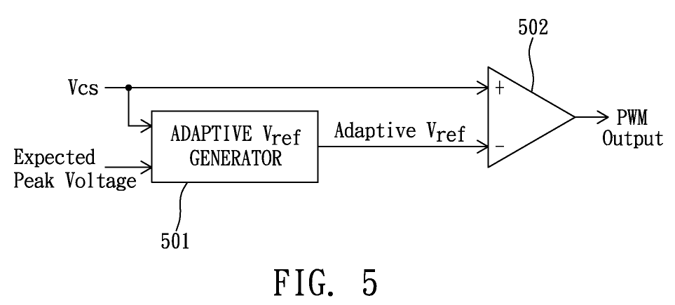

Please refer to FIG. 5, which shows the block diagram of an apparatus according to a preferred embodiment of the present invention, for regulating the peak value of a current sensing voltage V_{CS}. As shown in FIG. 5, the apparatus includes an adaptive reference voltage generator 501 and a comparator 502.

The adaptive reference voltage generator 501 is used to generate an adaptive V_{ref} according to voltage comparison of the current sensing voltage V_{CS} corresponding to the magnetic flux and an expected peak voltage, wherein the adaptive V_{ref} is stepped down by a predetermined value each time the current sensing voltage V_{CS} exceeds the expected peak voltage.

The comparator 502 is used for generating a PWM signal according to voltage comparison of the current sensing voltage V_{CS} and the adaptive V_{ref}.

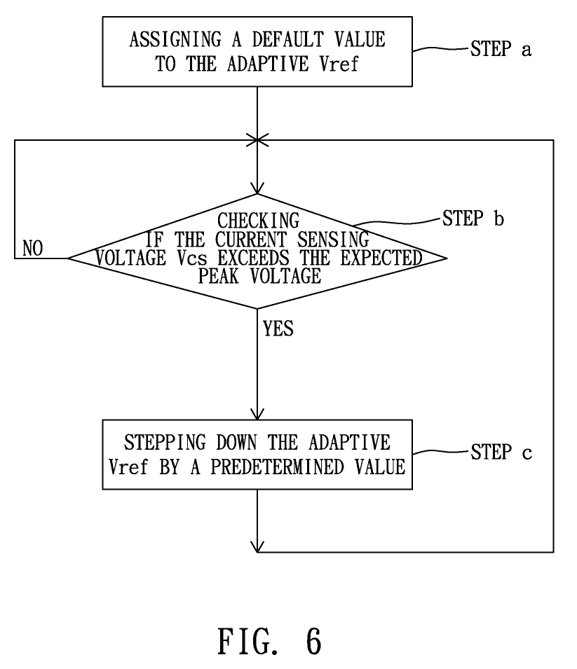

The adaptive V_{ref} is adjusted in a way as shown in the flow chart of FIG. 6. The flow chart includes the steps of: assigning a default value to the adaptive V_{ref} (step a); checking if the current sensing voltage V_{CS} exceeds the expected peak voltage (step b); and stepping down the adaptive V_{ref} by a predetermined value (step c).

In step a, the default value can be a value lower than the expected peak voltage.

In step b, if the checking result is true than the process will go to step c, otherwise it will go to step b.

In step c, the predetermined value is greater than the possible noise.

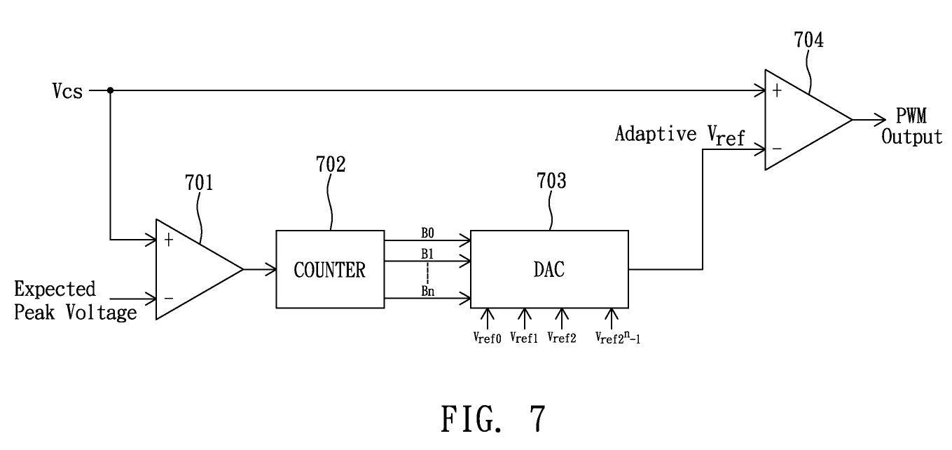

Please refer to FIG. 7, which shows the detailed block diagram of an apparatus according to a preferred embodiment of the present invention, for regulating the peak value of the current sensing voltage V_{CS}. As shown in FIG. 7, the apparatus includes a comparator 701, a counter 702, a digital to analog converter 703, and a comparator 704.

The comparator 701 is used to generate a trigger signal according to voltage comparison of the current sensing voltage V_{CS} and the expected peak voltage.

The counter 702 is used to generate a multi-bits digital output according to the trigger signal.

The digital to analog converter 703 is used to generate an adaptive V_{ref} according to the multi-bits digital output. If the counter 702 has an n bits digital output, than there will be 2ⁿ discrete values of the adaptive V_{ref}, which has a resolution equal to a predetermined value.

The comparator 704 is used to generate a PWM signal according to voltage comparison of the current sensing voltage V_{CS} and the adaptive V_{ref}.

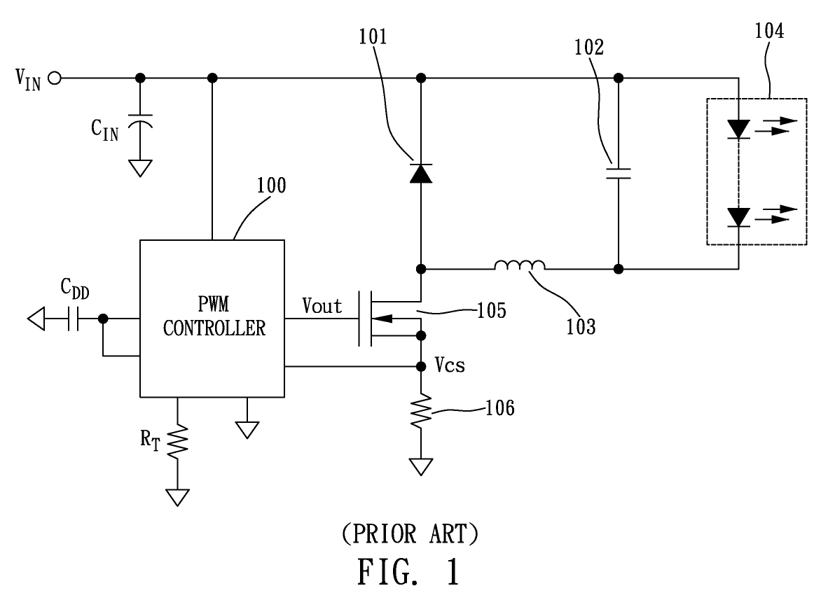

Using the apparatus for regulating the peak value of the current sensing voltage V_{CS} as illustrated in FIG. 7 to implement the PWM controller 100 in the typical open loop LED driving circuit as shown in FIG. 1, an open loop LED driving circuit capable of digitally regulating the peak magnetic flux of the inductor is proposed. As can be seen, the present invention doesn't need the information of the off delay.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance than the conventional structure and further complies with the patent application requirements and is submitted to the Patent and Trademark Office for review and granting of the commensurate patent rights.

What is claimed is:

1. A peak magnetic flux regulation method for a power conversion via magnetic flux transformation through an inductive component, comprising the steps of:
generating an adaptive reference voltage according to voltage comparison of a current sensing voltage corresponding to said magnetic flux and an expected peak voltage, wherein said adaptive reference voltage is stepped down by a predetermined value each time said current sensing voltage exceeds said expected peak voltage; and
generating a PWM signal according to voltage comparison of said current sensing voltage and said adaptive reference voltage.

2. The method according to claim 1, wherein said magnetic flux is proportional to an inductive current flowing through said inductive component.

3. The method according to claim 2, wherein said current sensing voltage is generated across a resistor carrying said inductive current.

4. The method according to claim 1, wherein said adaptive reference voltage can be one of 2ⁿ discrete values, wherein n is a positive integer and said 2ⁿ discrete values has a resolution equal to said predetermined value.

5. A peak magnetic flux regulation apparatus for a power conversion via magnetic flux transformation through an inductive component, comprising:
an adaptive reference voltage generator, used for generating an adaptive reference voltage according to voltage comparison of a current sensing voltage corresponding to said magnetic flux and an expected peak voltage, wherein said adaptive reference voltage is stepped down by a predetermined value each time said current sensing voltage exceeds said expected peak voltage; and
a first comparator, used for generating a PWM signal according to voltage comparison of said current sensing voltage and said adaptive reference voltage.

6. The apparatus according to claim 5, wherein said adaptive reference voltage generator comprises:
a second comparator, used to generate a trigger signal according to voltage comparison of said current sensing voltage and said expected peak voltage;
a counter, used to generate a multi-bits digital output according to said trigger signal; and
a digital to analog converter, used to generate said adaptive reference voltage according to said multi-bits digital output.

7. The apparatus according to claim 5, wherein said magnetic flux is proportional to an inductive current flowing through said inductive component.

8. The apparatus according to claim 6, wherein said current sensing voltage is generated across a resistor carrying said inductive current.

9. The apparatus according to claim 5, wherein said power conversion is an open loop current regulation application.

10. A system using a peak magnetic flux regulation apparatus for a power conversion via magnetic flux transformation through an inductive component, comprising:
an adaptive reference voltage generator, used for generating an adaptive reference voltage according to voltage comparison of a current sensing voltage corresponding to said magnetic flux and an expected peak voltage, wherein said adaptive reference voltage is stepped down by a predetermined value each time said current sensing voltage exceeds said expected peak voltage;
a first comparator, used for generating a PWM signal according to voltage comparison of said current sensing voltage and said adaptive reference voltage; and
a power conversion unit, responsive to said PWM signal to provide the power conduction path.

11. The system according to claim 10, wherein said power conversion is an open loop current regulation application.
